(19) United States
(12) Patent Application Publication
(10) Pub. No.: US 2026/0259879 A1
(43) Pub. Date: Sep. 3, 2026

(54) INFORMATION PROCESSING METHOD, INFORMATION PROCESSING APPARATUS, AND COMPUTER PROGRAM

(71) Applicant: Tokyo Electron Limited, Tokyo (JP)

(72) Inventors: Ruiki KOBAYASHI, Koshi City (JP); Takahiro NAKAMURA, Sapporo City (JP)

(73) Assignee: Tokyo Electron Limited, Tokyo (JP)

(21) Appl. No.: 19/657,254

(22) Filed: Apr. 24, 2026

Related U.S. Application Data
(63) Continuation of application No. PCT/JP2024/039023, filed on Nov. 1, 2024.

(30) Foreign Application Priority Data
Nov. 6, 2023 (JP) 2023-189582

(51) Int. Cl. G06F 16/2453; G06N 20/00

(52) U.S. Cl. CPC G06F 16/24542; G06N 20/00

(57) ABSTRACT

To provide an information processing method, an information processing apparatus, and a non-transitory computer-readable storage medium for easily implementing a base model for estimating information related to a substrate processing apparatus. In the information processing apparatus, data related to the substrate processing apparatus is input into a first model, and a first feature value output by the first model is acquired, a query related to the substrate processing apparatus is input into a second model, and a second feature value output by the second model is acquired, the first feature value and the second feature value are input into an integrated model, and an answer to the query output by the integrated model is acquired, and the acquired answer is output, the outputted answer includes information and data monitoring, operation, diagnosis, maintenance or prediction of the state or performance of the substrate processing apparatus.

### CROSS-REFERENCE TO RELATED APPLICATIONS

This application is a bypass continuation application of international application No. PCT/JP 2024/039023 having an international filing date of Nov. 1, 2024 and designating the United States, the international application being based upon and claiming the benefit of priority from Japanese Patent Application No. 2023-189582, filed on Nov. 6, 2023, the entire contents of each are incorporated herein by reference.

### TECHNICAL FIELD

The present disclosure relates to an information processing method, an information processing apparatus, and a computer program.

### BACKGROUND

A large language model (LLM) may be used to construct a base model for performing estimation. NPL 1 discloses an application of LLM.

### SUMMARY

The present disclosure provides an information processing method, an information processing apparatus, and a computer program for easily implementing a base model for estimating information related to a substrate processing apparatus.

An information processing method according to an aspect of the present disclosure includes: inputting data related to a substrate processing apparatus into a first model, and acquiring a first feature value output by the first model, inputting a query related to the substrate processing apparatus into a second model, and acquiring a second feature value output by the second model, inputting the first feature value and the second feature value into an integrated model, and acquiring an answer to the query output by the integrated model, and outputting the acquired answer, wherein the outputted answer comprises information and data monitoring, operation, diagnosis, maintenance or prediction of the state or performance of the substrate processing apparatus.

According to the present disclosure, the information processing method, the information processing apparatus, and the computer program for easily implementing the base model for estimating information related to the substrate processing apparatus can be provided.

### BRIEF DESCRIPTION OF DRAWINGS

FIG. 1 is a conceptual diagram illustrating a configuration example of a base model.

FIG. 2 is a table illustrating an example of contents of log data.

FIG. 3 is a table illustrating an example of performance data.

FIG. 4 is a block diagram illustrating an internal configuration example of an information processing apparatus.

FIG. 5 is a block diagram illustrating an example of an internal functional configuration of a training apparatus.

FIG. 6 is a conceptual diagram illustrating an example of contents of training data.

FIG. 7 is a flowchart illustrating an example of a procedure of processing performed by the training apparatus.

FIG. 8 is a flowchart illustrating a procedure of processing performed by the information processing apparatus.

FIG. 9 is a schematic diagram illustrating an example of an input image.

FIG. 10 is a conceptual diagram illustrating a first example of a result of repeating processing of steps S21 to S25.

FIG. 11 is a conceptual diagram illustrating a second example of the result of repeating the processing of steps S21 to S25.

FIG. 12 is a conceptual diagram illustrating a third example of the result of repeating the processing of steps S21 to S25.

FIG. 13 is a conceptual diagram illustrating a fourth example of the result of repeating the processing of steps S21 to S25.

FIG. 14 is a conceptual diagram illustrating a fifth example of the result of repeating the processing of steps S21 to S25.

### DETAILED DESCRIPTION

Hereinafter, the present disclosure will be specifically described with reference to the drawings illustrating an embodiment thereof.

In the related art, it has been necessary to have a base model for each substrate processing apparatus or to tune the base model for each substrate processing apparatus. Therefore, it may be difficult to develop or operate the base model. There is a need to estimate any information not obtained with respect to a substrate processing apparatus from any data obtained with respect to the substrate processing apparatus that performs processing such as etching or film formation on a substrate such as a semiconductor wafer or a glass substrate. For example, it may be desired to estimate performance of substrate processing based on log data indicating a history of a state of the substrate processing apparatus and data indicating a state of the substrate before processing. An information processing method according to an aspect of the present disclosure includes: inputting data related to a substrate processing apparatus into a first model, and acquiring a first feature value output by the first model, inputting a query related to the substrate processing apparatus into a second model, and acquiring a second feature value output by the second model, inputting the first feature value and the second feature value into an integrated model, and acquiring an answer to the query output by the integrated model, and outputting the acquired answer.

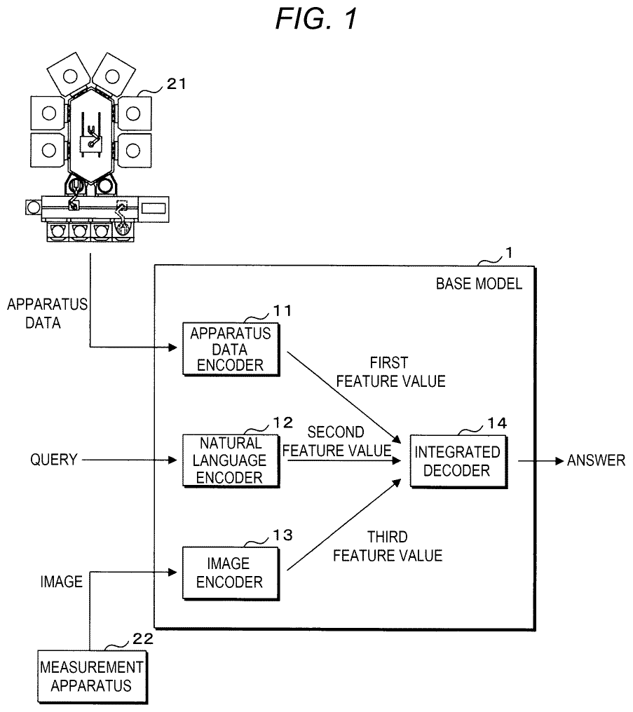

In the present embodiment, a process of generating desired information is performed using a base model from data related to a substrate processing apparatus. FIG. 1 is a conceptual diagram illustrating a configuration example of a base model 1. The base model 1 includes an apparatus data encoder 11, a natural language encoder 12, an image encoder 13, and an integrated decoder 14.

The apparatus data encoder 11 is a trained model that is trained to receive apparatus data related to a substrate processing apparatus 21 and output a first feature value according to the input apparatus data. The apparatus data encoder 11 performs a calculation to generate the first feature value representing a feature of the apparatus data. The apparatus data encoder 11 corresponds to a first model. The apparatus data is input from, for example, the substrate processing apparatus 21 to the apparatus data encoder 11. The apparatus data may be input from a control device that controls the substrate processing apparatus 21 to the apparatus data encoder 11.

The natural language encoder 12 is a trained model that is trained to receive some type of query expressed in natural language and output a second feature value according to the input query. The natural language encoder 12 performs a calculation to generate the second feature value representing a feature of the query. The natural language encoder 12 corresponds to a second model. The query is input from a user, for example. The query requests some information from the base model 1.

The image encoder 13 is a trained model that is trained to receive an image related to substrate processing and output a third feature value according to the input image. The image encoder 13 performs a calculation to generate the third feature value representing a feature of an image. The image encoder 13 corresponds to a third model. The image related to the substrate processing is, for example, an image representing a shape of the substrate. The image related to the substrate processing is generated by, for example, a measurement apparatus 22 that measures the shape of the substrate, and is input from the measurement apparatus 22 to the image encoder 13.

The measurement apparatus 22 is, for example, an imaging apparatus that captures an image of a substrate. An image captured by the measurement apparatus 22 that is an imaging apparatus is input into the image encoder 13. Alternatively, the measurement apparatus 22 may be a measuring instrument such as a sensor, or may be configured to generate an image based on measured values such as a graph representing changes in the measured values over time. An image based on the measured value measured by the measurement apparatus 22 that is a measuring instrument is input into the image encoder 13.

The integrated decoder 14 is a trained model that is trained to receive the first feature value, the second feature value, and the third feature value and output an answer to the query. The integrated decoder 14 performs a calculation to generate an answer to the query based on a correlation between the first feature value, the second feature value, and the third feature value. The integrated decoder 14 corresponds to an integrated model. The integrated decoder 14 is trained to output an answer even when no image is input into the image encoder 13 and no third feature value is input into the integrated decoder 14. The integrated decoder 14 is trained to output an answer even when no apparatus data is input into the apparatus data encoder 11 and no first feature value is input into the integrated decoder 14.

The apparatus data encoder 11, the natural language encoder 12, the image encoder 13, and the integrated decoder 14 are each implemented using a neural network. For example, the apparatus data encoder 11 or the image encoder 13 is implemented using a convolutional neural network (CNN). The natural language encoder 12 may be implemented using a language model such as BERT, GPT-4, Bard, or LLaMA. The integrated decoder 14 may be implemented using GPT. A request for information related to the substrate processing apparatus 21 is input as a query into the base model 1, and requested information related to the substrate processing apparatus 21 is output from the base model 1 as an answer to the query.

The apparatus data input into the apparatus data encoder 11 is data related to the substrate processing apparatus 21. The apparatus data is, for example, data representing a state of the substrate processing apparatus 21. More specifically, the apparatus data is sensor data obtained from a sensor provided in the substrate processing apparatus 21, for example. The sensor data represents changes in a physical quantity over time measured by the sensor such as temperature, pressure, current, or voltage. The sensor data may represent a spatial distribution of physical quantities. The sensor data may be data of an optical emission spectrometer (OES). The apparatus data may include a plurality of types of sensor data obtained from a plurality of sensors provided in the substrate processing apparatus 21. The sensor data represents changes in the state of the substrate processing apparatus 21 by numerical values. The plurality of types of sensor data represent changes in the state of the substrate processing apparatus 21 in more detail. Changes in the state of the substrate processing apparatus 21 such as temperature changes in the substrate processing apparatus 21 affect information on the substrate processing apparatus 21 such as a result of substrate processing. Therefore, the answer output from the base model 1 may change according to the sensor data.

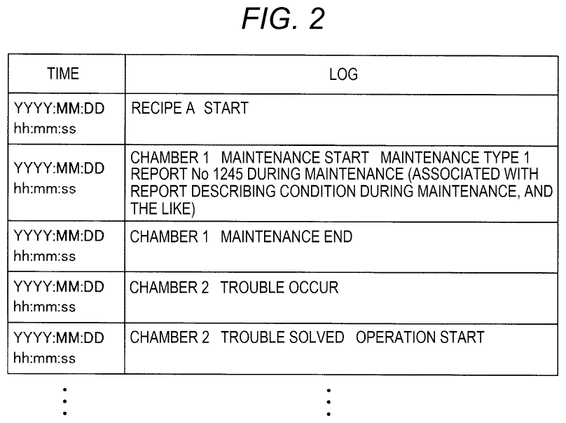

The apparatus data may be log data showing a history of the state of the substrate processing apparatus 21. FIG. 2 is a table illustrating an example of contents of log data. In a table format, times and events that have occurred in the substrate processing apparatus 21 at respective times are recorded. As illustrated in FIG. 2, log data records a history of the state of the substrate processing apparatus 21 over time, such as a history of contents of an operation of the substrate processing apparatus 21, a history of maintenance of the substrate processing apparatus 21, and a history of a trouble that occurred in the substrate processing apparatus 21. Changes in the state of the substrate processing apparatus 21, such as a state of the operation of the substrate processing apparatus 21 or presence or absence of maintenance, affect information regarding the substrate processing apparatus 21, such as a result of substrate processing. Therefore, the answer output from the base model 1 may change according to the log data. The log data does not need to be in a table format. Alternatively, the apparatus data may be recipe data defining contents of the substrate processing.

The image related to the substrate processing input into the image encoder 13 is, for example, an image representing a shape of the substrate. More specifically, the image related to substrate processing is, for example, an image obtained by imaging a surface of the substrate before or after processing with a camera. The image related to the substrate processing is, for example, an image representing a surface or cross-section of the substrate before or after the processing measured by a scanning electron microscope (SEM). The image related to the substrate processing may be an image representing the shape of the substrate measured using, for example, laser light, radio waves, or ultrasonic waves. The image related to the substrate processing may be, for example, an image representing a distribution of components of the substrate obtained through a spectral analysis such as emission spectroscopy or a fluorescence analysis. The image related to the substrate processing is not limited to an image representing the entire substrate. For example, the image related to the substrate processing may be an image obtained by imaging a part of the substrate such as a bevel portion of the substrate.

The image related to the substrate processing is not limited to the image related to the substrate itself. The image related to the substrate processing may be an image representing the state of the substrate processing apparatus 21. For example, the image may be an image obtained by imaging an entire or a part of an inside of a process chamber in the substrate processing apparatus 21. The image related to the substrate processing may be an image based on information that has any relationship with a state of the substrate or the substrate processing apparatus 21 before, after, or during the processing. For example, an image with a wavelength axis and a time axis obtained from OES data may be used as the image related to the substrate processing. For example, an image generated based on a result of measuring the substrate with a reflectometer may be used. For example, an image generated based on a measured value obtained by a sensor provided in the substrate processing apparatus 21 or the measurement apparatus 22 may be used. The image generated based on the measured value is, for example, a graph representing a change in the measured value over time, or an image representing a result of performing a Fourier transform on a time series of the measured value for a short time.

An answer output from the integrated decoder 14 is an answer to the query input into the natural language encoder 12. The answers output from the integrated decoder 14 include text, numerical data, tabular data, graphs, or images. For example, an inquiry as to what data is required for estimating a result of substrate processing as a query is input into the natural language encoder 12, and a proposal of data required for estimating the result of the substrate processing is output from the integrated decoder 14 as an answer. For example, a request for a result of the substrate processing is input into the natural language encoder 12 as a query, sensor data or log data is input into the apparatus data encoder 11, and an image of the substrate before processing is input into the image encoder 13. In this case, for example, performance data indicating performance of the substrate processing is output from the apparatus data encoder 11.

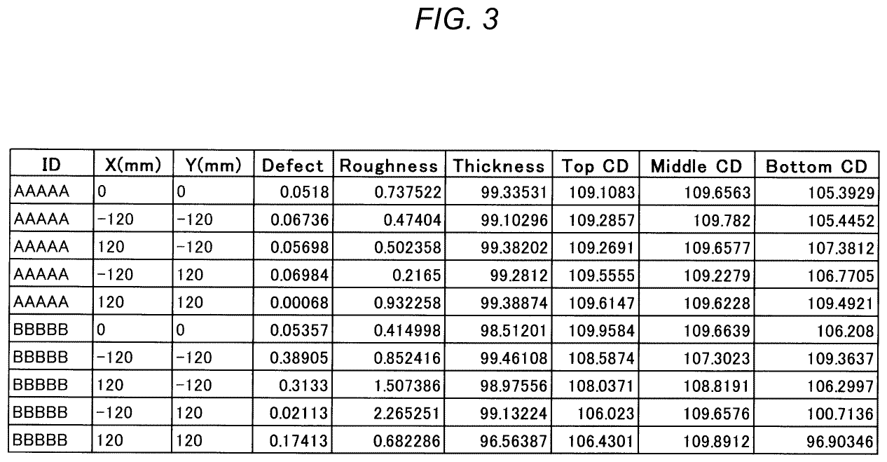

FIG. 3 is a table illustrating an example of performance data. Results of measuring a surface shape of the processed substrate are recorded in a table format. In association with an ID of the substrate or the measurement, numerical values representing a location on the substrate where the measurement is performed, roughness, a surface shape, and the like are recorded. In the example illustrated in FIG. 3, IDs indicating two substrates, AAAAA and BBBBB, are recorded, respectively. In the drawing, X and Y represent locations on the substrate where measurement is performed, and Defect, Roughness, and Thickness represent the amount of defects, surface roughness, and thickness, respectively, at the locations where measurement is performed. CD (critical dimension) indicates a width of a groove formed in the substrate, and Top CD, Middle CD, and Bottom CD indicate a CD at an upper end, a center in a depth direction, and a bottom of the groove, respectively. The performance data may be data in a format other than a table format, such as an image or a graph.

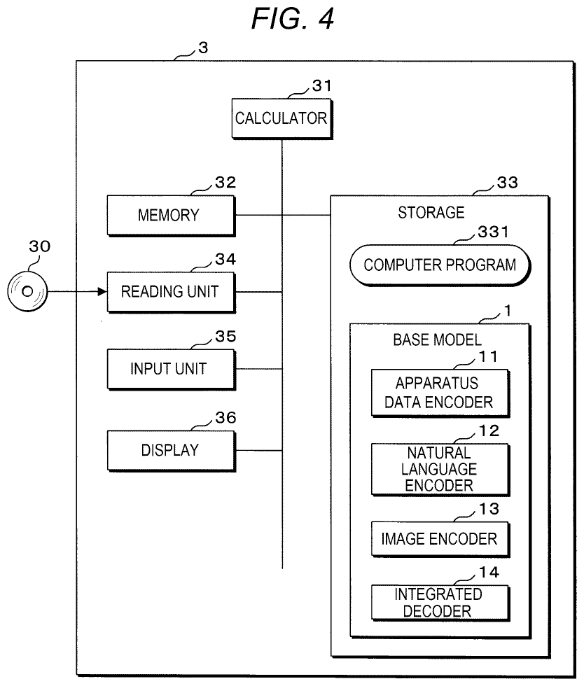

The base model 1 is implemented by an information processing apparatus. FIG. 4 is a block diagram illustrating an internal configuration example of an information processing apparatus 3. The information processing apparatus 3 executes an information processing method. The information processing apparatus 3 is implemented using a computer such as a personal computer or a server device. The information processing apparatus 3 includes a calculator 31 (i.e., circuitry), a memory 32, a storage 33, a reading unit 34, an input unit 35, and a display 36. The calculator 31 is implemented using, for example, a central processing unit (CPU), a graphics processing unit (GPU), or a multi-core CPU. The calculator 31 may also be implemented using a quantum computer. The memory 32 stores temporary data generated along with a calculation. The memory 32 is, for example, a random access memory (RAM). The storage 33 is non-volatile, and is, for example, a hard disk or a non-volatile semiconductor memory. The reading unit 34 reads information from a recording medium 30 such as an optical disk or a portable memory. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The input unit 35 receives an input of data. The input unit 35 includes an operation unit that receives an input of information such as text by receiving an operation from a user. The operation unit is, for example, a touch panel, a keyboard, or a pointing device. For example, a query is input by the operation unit. The input unit 35 may include an input interface to receive apparatus data from the substrate processing apparatus 21 or the control device that controls the substrate processing apparatus 21, or image data from the measurement apparatus 22. Data may be input into the input unit 35 by a method other than the method input from the substrate processing apparatus 21, the control device, or the measurement apparatus 22. The display 36 displays an image. The display 36 is, for example, a liquid crystal display or an electroluminescent display (EL display).

The calculator 31 causes the reading unit 34 to read a computer program 331 recorded in the recording medium 30, and causes the storage 33 to store the read computer program 331. The calculator 31 executes processing for implementing functions of the information processing apparatus 3 according to the computer program 331. The computer program 331 may be a program product. The computer program 331 may be stored in advance in the storage 33 or may be downloaded from outside the information processing apparatus 3. In this case, the information processing apparatus 3 does not need to be provided with the reading unit 34.

The computer program 331 may be loaded to be executed on a single computer or on a plurality of computers disposed at one site or distributed across a plurality of sites and interconnected by a communication network. That is, the information processing apparatus 3 may be implemented by a plurality of computers, and the computer program 331 may be executed on the plurality of computers connected via the communication network. The information processing apparatus 3 may be implemented using a cloud server.

The information processing apparatus 3 includes the base model 1. The base model 1 includes the apparatus data encoder 11, the natural language encoder 12, the image encoder 13, and the integrated decoder 14. The apparatus data encoder 11, the natural language encoder 12, the image encoder 13, and the integrated decoder 14 are implemented by the calculator 31 performing information processing according to the computer program 331. As described above, each of the apparatus data encoder 11, the natural language encoder 12, the image encoder 13, and the integrated decoder 14 is implemented using a neural network.

Any one of the apparatus data encoder 11, the natural language encoder 12, the image encoder 13, and the integrated decoder 14 may be implemented using hardware. For example, any of the apparatus data encoder 11, the natural language encoder 12, the image encoder 13, and the integrated decoder 14 may be implemented by hardware that includes a processor and a memory that stores necessary programs and data. Alternatively, any of the apparatus data encoder 11, the natural language encoder 12, the image encoder 13, and the integrated decoder 14 may be implemented using a quantum computer. Alternatively, any of the apparatus data encoder 11, the natural language encoder 12, the image encoder 13, and the integrated decoder 14 may be provided outside the information processing apparatus 3, and the information processing apparatus 3 may be configured to perform processing using the external apparatus data encoder 11, natural language encoder 12, image encoder 13, or integrated decoder 14. For example, any of the apparatus data encoder 11, the natural language encoder 12, the image encoder 13, and the integrated decoder 14 may be implemented using a cloud.

Among the apparatus data encoder 11, the natural language encoder 12, the image encoder 13, and the integrated decoder 14, the natural language encoder 12 and the image encoder 13 are general-purpose trained models. In the present embodiment, training of the base model 1 is performed without training the natural language encoder 12 and the image encoder 13. The training of the base model 1 is performed by a training apparatus 4.

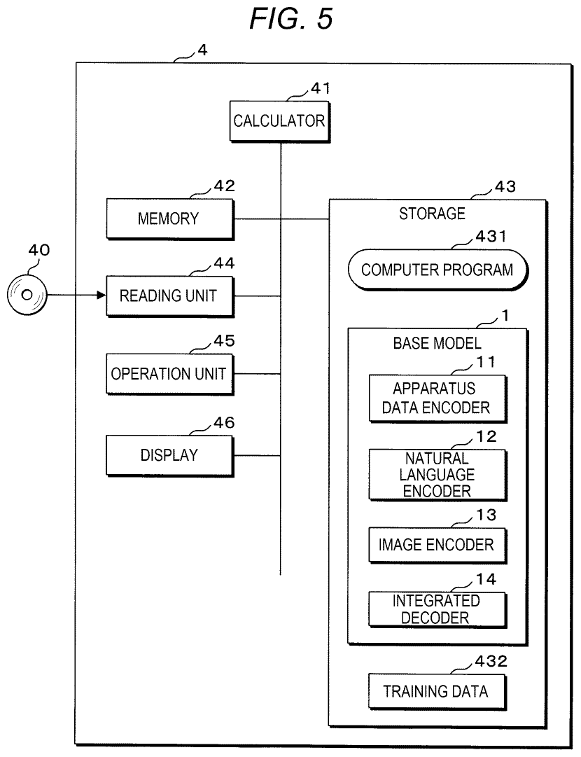

FIG. 5 is a block diagram illustrating an example of an internal functional configuration of the training apparatus 4. The training apparatus 4 is a computer such as a server device or a personal computer. The training apparatus 4 includes a calculator 41, a memory 42, a storage 43, a reading unit 44, an operation unit 45, and a display 46. The calculator 41 is implemented using, for example, a CPU, a GPU, or a multi-core CPU. The calculator 41 may also be implemented using a quantum computer. The memory 42 stores temporary data generated along with a calculation. The memory 42 is, for example, a RAM. The reading unit 44 reads information from a recording medium 40 such as an optical disk or a portable memory. The storage 43 is non-volatile, and is, for example, a hard disk or a non-volatile semiconductor memory.

The operation unit 45 receives an input of information by receiving an operation from a user. The operation unit 45 is, for example, a keyboard, a pointing device, or a touch panel. The display 46 displays an image. The display 46 is, for example, a liquid crystal display or an EL display.

A computer program 431 may be loaded to be executed on a single computer or on a plurality of computers disposed at one site or distributed across a plurality of sites and interconnected by a communication network. That is, the training apparatus 4 may be implemented by a plurality of computers, and the computer program 431 may be executed on the plurality of computers connected via the communication network. The training apparatus 4 may be implemented using a cloud server.

The training apparatus 4 executes a part of the information processing method. More specifically, the training apparatus 4 performs processing of training the apparatus data encoder 11 and the integrated decoder 14. The training apparatus 4 includes the base model 1 that includes the apparatus data encoder 11, the natural language encoder 12, the image encoder 13, and the integrated decoder 14. The apparatus data encoder 11, the natural language encoder 12, the image encoder 13, and the integrated decoder 14 are all trained models. The base model 1 is implemented by executing processing by the calculator 41 according to the computer program 431. Parameters necessary for the apparatus data encoder 11, the natural language encoder 12, the image encoder 13, and the integrated decoder 14 to perform a calculation are stored in the storage 43, for example.

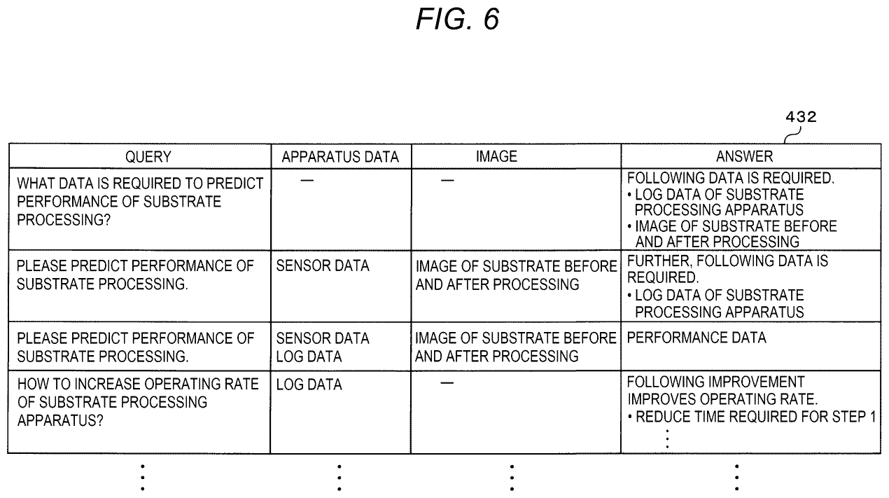

The storage 43 stores training data 432 for training the base model 1. FIG. 6 is a conceptual diagram illustrating an example of contents of the training data 432. In the training data, a query, apparatus data, an image, and an answer to the query are recorded in association with each other. The query, the apparatus data, and the image to be input into the base model 1 are associated with the answer to be output from the base model 1 when the query, the apparatus data, and the image are input. A plurality of data sets are recorded in the training data 432 using a combination of the query, apparatus data, image, and answer as one data set.

The apparatus data in the training data 432 is, for example, data obtained from the actual substrate processing apparatus 21 or a control device that controls the actual substrate processing apparatus 21. The image is, for example, an image actually obtained by the measurement apparatus 22. The apparatus data or image may be processed from actually obtained apparatus data or image, or may be freely created. The plurality of data sets may include data sets in which some or all of contents of the query, the apparatus data, the image, or the answer are blank.

The answer in the training data 432 may be created based on a manual or specifications of the substrate processing apparatus 21. The answer may be freely created so as to be an answer corresponding to the query. The data in the answer such as the performance data may be data obtained through actual substrate processing, data obtained in practice may be processed, or may be data freely created. Not only the single substrate processing apparatus 21 but also a large number of data sets in which queries, apparatus data, images, and answers related to various types of substrate processing apparatuses are associated with each other are recorded in the training data 432. With respect to each type of substrate processing apparatus, a large number of data sets are recorded in the training data 432. The training data 432 may include a data set in which queries, apparatus data, images, and answers related to different types of substrate processing apparatuses are associated with each other.

The training apparatus 4 uses the training data to train the base model 1. Pre-training may be performed on the base model 1 before training using the training data. For example, based on a manual or specification of the substrate processing apparatus 21, training is performed such that a query requesting creation of a correct sentence from a sentence related to the substrate processing apparatus 21 that has been partially masked is input into the base model 1, and the correct sentence is output from the base model 1 as an answer. For example, based on a report on substrate processing performed in the past by the substrate processing apparatus 21, training is performed such that apparatus data and a query requesting a substrate processing result are input into the base model 1, and the substrate processing result such as performance data is output from the base model 1 as the answer. The pre-training may be performed by the training apparatus 4, and the base model 1 for which the pre-training has been performed may be deployed to the training apparatus 4.

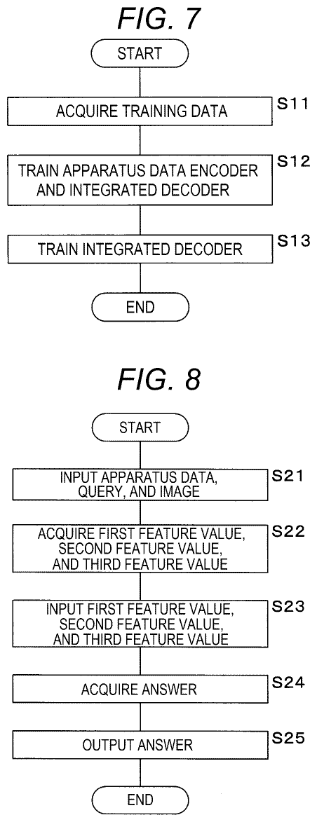

FIG. 7 is a flowchart illustrating an example of a procedure of processing performed by the training apparatus 4. Hereinafter, step will be abbreviated as S. The calculator 41 performs information processing according to the computer program 431, and thus the training apparatus 4 performs the following processing. When the calculator 41 reads the training data 432 stored in the storage 43, the training apparatus 4 acquires the training data 432 (S11). In step S11, the training apparatus 4 may acquire the training data 432 by inputting the training data 432 from the outside.

The training apparatus 4 then uses the training data 432 to collectively train the apparatus data encoder 11 and the integrated decoder 14 (S12). In step S12, the calculator 41 inputs the query, the apparatus data, and the image in the training data 432 into the base model 1. More specifically, the calculator 41 inputs the query in the training data 432 into the natural language encoder 12, and inputs the apparatus data associated with the query in the training data 432 into the apparatus data encoder 11. The calculator 41 inputs the image associated with the query in the training data 432 into the image encoder 13. When contents of the apparatus data or the image are blank, nothing is input into the apparatus data encoder 11 or the image encoder 13, or given data corresponding to the blank is input into the apparatus data encoder 11 or the image encoder 13.

The apparatus data encoder 11 performs a calculation according to the input of the apparatus data, outputs the first feature value, and inputs the first feature value into the integrated decoder 14. The natural language encoder 12 performs a calculation according to the input of the query, outputs the second feature value, and inputs the second feature value into the integrated decoder 14. The image encoder 13 performs a calculation according to the input of the image, outputs the third feature value, and inputs the third feature value into the integrated decoder 14. The integrated decoder 14 performs a calculation according to the inputs of the first feature value, the second feature value, and the third feature value, and outputs an answer to the query. In other words, the answer is output from the base model 1.

Although all of the apparatus data encoder 11, the natural language encoder 12, the image encoder 13, and the integrated decoder 14 participate in the forward pass calculation during step S12, only the parameters of the apparatus data encoder 11 and the integrated decoder 14 are updated while the natural language encoder 12 and the image encoder 13 are fixed. That is, The calculator 41 adjusts parameters of the calculations of the apparatus data encoder 11 and the integrated decoder 14 such that an error between the answer output by the base model 1 and an answer associated with the query, the apparatus data, and the image input into the base model 1 in the training data 432 becomes small. For example, the calculator 41 adjusts the parameters by a back propagation method. At this time, the calculator 41 fixes parameters for the natural language encoder 12 and the image encoder 13. In this way, the apparatus data encoder 11 and the integrated decoder 14 are trained without training the natural language encoder 12 and the image encoder 13. The calculator 41 repeats the processing using a plurality of data sets recorded in the training data 432 to adjust the parameters of the calculations of the apparatus data encoder 11 and the integrated decoder 14, thereby performing machine learning of the apparatus data encoder 11 and the integrated decoder 14.

The training apparatus 4 then trains the integrated decoder 14 using the training data 432 (S13). In step S13, the calculator 41 inputs the query, the apparatus data, and the image in the training data 432 into the base model 1, as in step S12. The apparatus data encoder 11, the natural language encoder 12, and the image encoder 13 output the first feature value, the second feature value, and the third feature value, and input these to the integrated decoder 14, and the integrated decoder 14 outputs an answer.

The calculator 41 adjusts the parameter of the calculation of the integrated decoder 14 such that the error between the answer output by the base model 1 and the answer associated with the query, the apparatus data, and the image input into the base model 1 in the training data 432 becomes small. At this time, the calculator 41 fixes the parameters for the apparatus data encoder 11, the natural language encoder 12, and the image encoder 13. In this way, only the integrated decoder 14 is trained. The calculator 41 repeats the processing using a plurality of data sets recorded in the training data 432 to adjust the parameters of the calculation of the integrated decoder 14, thereby performing machine learning of the integrated decoder 14.

Alternatively, the learning of the integrated decoder 14 may be performed by learning using human feedback. The calculator 41 acquires the answer output from the base model 1 and displays the answer on the display 46. The user checks the displayed answer, determines a difference between the displayed answer and the appropriate answer to be output, and inputs information indicating the determined difference into the training apparatus 4 by operating the operation unit 45. The calculator 41 adjusts the parameter of the calculation of the integrated decoder 14 such that an error corresponding to the input difference becomes small. The query, the apparatus data, or the image input into the base model 1 may be input into the training apparatus 4 by the user operating the operation unit 45.

In step S12 or S13, the calculator 41 may perform training such that a query requesting reconstruction of the apparatus data or the image is input into the base model 1, and the apparatus data or the image reconstructed from the base model 1 is output. Since training is performed using a large number of data sets related to various types of substrate processing apparatuses recorded in the training data 432, the base model 1 is a model adapted to various types of substrate processing apparatuses. The training is performed using a large number of data sets related to individual types of substrate processing apparatuses. In this way, the base model 1 is trained to be applied to various settings, situations, and environments related to various substrate processing apparatuses, and can appropriately output according to various inputs. The calculator 41 stores the final parameters adjusted in steps S12 and S13 in the storage 43. After S13 is ended, the training apparatus 4 ends the processing.

The base model 1 in which the apparatus data encoder 11 and the integrated decoder 14 have been trained by the processing in steps S11 to S13 is deployed in the information processing apparatus 3. For example, the parameter of the final base model 1 adjusted by the processing in steps S11 to S13 is input into the information processing apparatus 3 through the input unit 35 and stored in the storage 33. The calculator 31 performs information processing using the stored parameter, so that the base model 1 is implemented. The information processing apparatus 3 may also function as the training apparatus 4. In other words, the processing in steps S11 to S13 may be performed by the information processing apparatus 3. The base model 1 in which the apparatus data encoder 11 and the integrated decoder 14 have been trained based on data related to various types of substrate processing apparatuses can input and output information related to various types of substrate processing apparatuses.

The information processing apparatus 3 uses the base model 1 to perform processing for estimating various types of information related to the substrate processing apparatus 21. FIG. 8 is a flowchart illustrating a procedure of processing performed by the information processing apparatus 3. The information processing apparatus 3 performs the following processing by the calculator 31 performing the information processing according to the computer program 331. The information processing apparatus 3 inputs the apparatus data, the query, and the image into the base model 1 (S21). In step S21, the apparatus data is input from the substrate processing apparatus 21 or the control device to the input unit 35, the query is input by the user operating the operation unit in the input unit 35, and the image is input from the measurement apparatus 22 to the input unit 35. The information processing apparatus 3 inputs a prompt that includes the input query, and the selected apparatus data and image into the base model 1.

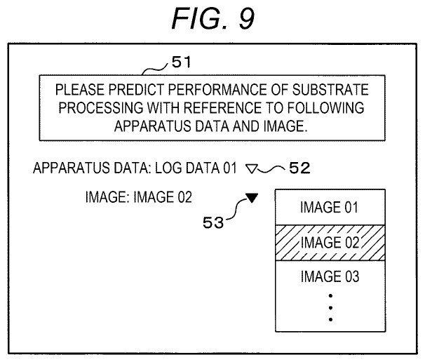

For example, the information processing apparatus 3 displays an input image on the display 36, and uses the input image to input apparatus data, a query, and an image. FIG. 9 is a schematic diagram illustrating an example of the input image. The input image includes an input field 51 for inputting a query. When the user operates the operation unit in the input unit 35, a query is input into the input field 51 in a text format. The input image includes selection icons 52 and 53 for selecting the apparatus data and the image. When the selection icons 52 or 53 in the input image are designated by the user operating the operation unit, a plurality of pieces of apparatus data or images stored in the storage 33 are displayed, and the apparatus data or image to be input is selected. FIG. 9 illustrates an example in which “log data 01” is selected as the apparatus data, and “image 02” is selected from a plurality of images.

The calculator 31 generates an input image that includes the input field 51, and the selection icons 52 and 53, and performs processing of displaying the input image on the display 36. A positional relationship between the input field 51 and the selection icons 52 and 53 illustrated in FIG. 9 is an example, and the input field 51 and the selection icons 52 and 53 may be disposed at other positions. A user interface for inputting the apparatus data or the image may be a form other than the selection icons 52 and 53. The calculator 31 may display a plurality of input images on the display 36, and the input field 51 and the user interface for inputting the apparatus data or the images may be in separate input images. The calculator 31 receives the apparatus data, the query, and the image input by the user operating the operation unit using the input image.

In step S21, the calculator 31 inputs the apparatus data into the apparatus data encoder 11, inputs the query into the natural language encoder 12, and inputs the image into the image encoder 13. The apparatus data or the image may be blank. The calculator 31 may input a prompt that includes, in addition to the query, a content of referring to the apparatus data or the image, to the natural language encoder 12. For example, the calculator 31 may generate a prompt including information designating apparatus data or an image, such as “please refer to following log data and images before and after substrate processing to generate performance data. {log data 01.csv}, {image 01.jpeg}, and {image 01.jpeg})”, and input the prompt into the natural language encoder 12. At this time, the calculator 31 inputs the apparatus data or the images referred to at the prompt into the apparatus data encoder 11 or the image encoder 13.

After the apparatus data, the query, and the image are input into the base model 1, the apparatus data encoder 11 performs a calculation, and outputs the first feature value according to the input apparatus data. The natural language encoder 12 performs a calculation, and outputs the second feature value according to the input query. The image encoder 13 performs a calculation, and outputs the third feature value according to the input image.

Next, the information processing apparatus 3 acquires the first feature value, the second feature value, and the third feature value (S22). In step S22, the calculator 31 acquires the first feature value, the second feature value, and the third feature value output from the apparatus data encoder 11, the natural language encoder 12, and the image encoder 13. The information processing apparatus 3 inputs the acquired first feature value, second feature value, and third feature value into the integrated decoder 14 (S23). The integrated decoder 14 performs a calculation, and outputs an answer according to the input first feature value, the second feature value, and the third feature value.

The information processing apparatus 3 acquires an answer to the query output by the base model 1 (S24). In step S24, the calculator 31 acquires an answer to the query output from the integrated decoder 14, and the information processing apparatus 3 outputs the acquired answer (S25). In step S25, the calculator 31 displays the answer to the query on the display 36. The calculator 31 stores the acquired answers in the storage 33. After step S25, the information processing apparatus 3 ends the processing.

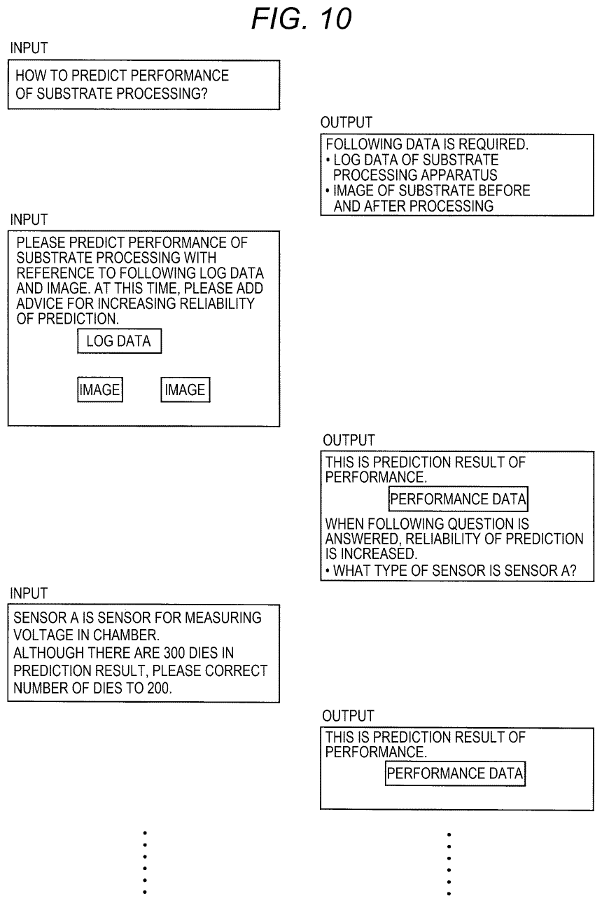

The information processing apparatus 3 performs the processing of steps S21 to S25 as necessary. For example, the information processing apparatus 3 repeats the processing of steps S21 to S25 according to an operation from the user. FIG. 10 is a conceptual diagram illustrating a first example of a result of repeating processing of steps S21 to S25. FIG. 10 illustrates examples of contents of the query and the like input into the base model 1 and answers output from the base model 1. A query inquiring about a method for estimating performance of substrate processing is input, and an answer designating necessary data is output. The query, the log data as the apparatus data, and the image are input, and the performance data corresponding to the log data and the image is output as an answer.

As illustrated in FIG. 10, a prompt may be input into the base model 1 that includes, in addition to the query, a request for advice for improving a quality of the answer such as performance data. As a result of repeating the processing according to the advice, an answer such as performance data with a further improved quality is output. The calculator 31 can display the performance data as illustrated in FIG. 3 on the display 36.

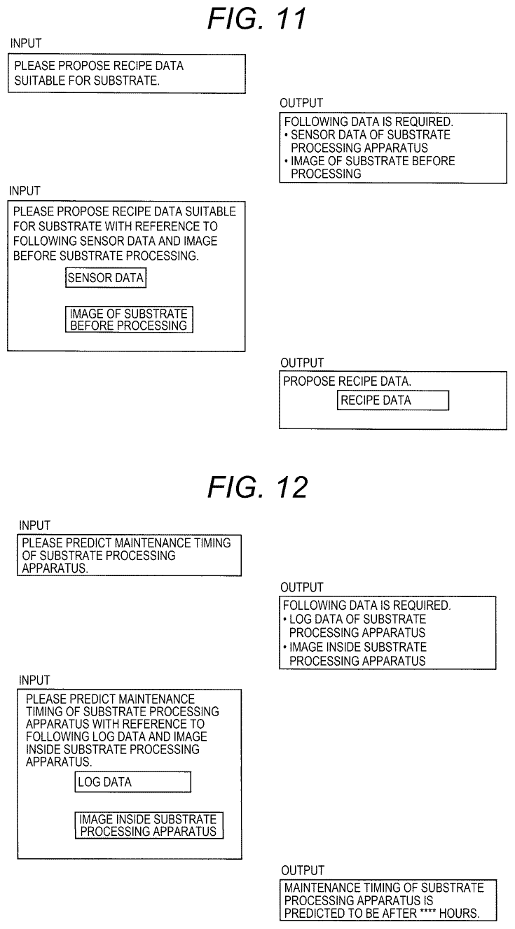

FIG. 11 is a conceptual diagram illustrating a second example of the result of repeating the processing of steps S21 to S25. A query requesting a proposal of recipe data suitable for the substrate is input, and an answer designating sensor data of the substrate processing apparatus 21 and an image of the substrate before processing is output as necessary data. The query, the sensor data that is the apparatus data, and the image of the substrate before processing are input, and the recipe data is output as the answer.

FIG. 12 is a conceptual diagram illustrating a third example of the result of repeating the processing of steps S21 to S25. A query requesting prediction of a maintenance timing of the substrate processing apparatus 21 is input, and an answer designating log data of the substrate processing apparatus 21 and an image inside the substrate processing apparatus 21 is output as necessary data. For example, the image inside the substrate processing apparatus 21 is an image obtained by imaging an inside of a process chamber of the substrate processing apparatus 21. The query, the log data that is the apparatus data, and the image inside the substrate processing apparatus 21 are input, and as the answer, a result obtained by estimating the maintenance timing of the substrate processing apparatus 21 is output.

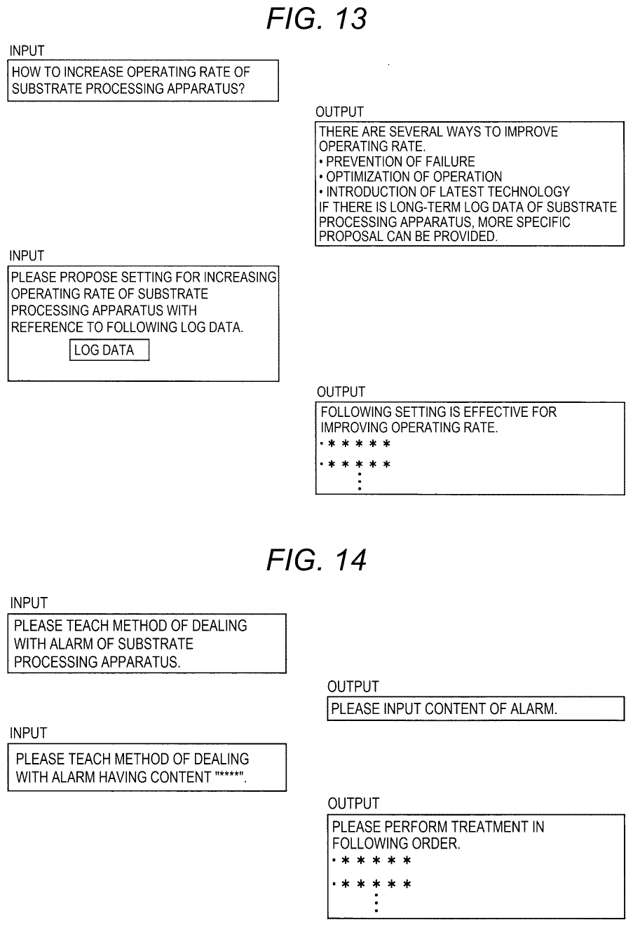

FIG. 13 is a conceptual diagram illustrating a fourth example of the result of repeating the processing of steps S21 to S25. A query inquiring about a method for increasing an operating rate of the substrate processing apparatus 21 is input, and an answer designating log data of the substrate processing apparatus 21 is output as necessary data. A query requesting a setting proposal for increasing the operating rate of the substrate processing apparatus 21 and log data that is apparatus data are input, and as an answer, an effective setting for improving the operating rate of the substrate processing apparatus 21 is output.

FIG. 14 is a conceptual diagram illustrating a fifth example of the result of repeating the processing of steps S21 to S25. A query for inquiring about a method of dealing with an alarm of the substrate processing apparatus 21 is input, and an answer requesting an input of a content of the alarm is output. The alarms are various alarms that are output from the substrate processing apparatus 21. After designating the content of the alarm, a query for inquiring about the method of dealing with the alarm is input, and the method of dealing with the alarm is output as an answer. As illustrated in FIGS. 10 to 14, the inputting of a query or the like into the base model 1 and the outputting from the base model 1 are appropriately repeated. The answer output from the base model 1 may take various forms, such as character strings, data files, or images, according to a query, apparatus data, or an image input into the base model 1. The user can estimate various types of information related to the substrate processing apparatus by adjusting inputs to the base model 1.

As described in detail above, the apparatus data is input into the apparatus data encoder 11, the first feature value is output, the query is input into the natural language encoder 12, the second feature value is output, the image is input into the image encoder 13, and the third feature value is output. The first feature value, the second feature value, and the third feature value are input to the integrated decoder 14, and an answer to the query is output. The base model 1 including the apparatus data encoder 11, the natural language encoder 12, the image encoder 13, and the integrated decoder 14 is obtained. The natural language encoder 12 and the image encoder 13 are used as general-purpose trained models, and the apparatus data encoder 11 and the integrated decoder 14 are trained so as to be applied to various substrate processing apparatuses, as a result, the base model 1 that estimates information related to various substrate processing apparatuses can be implemented.

The base model 1 thus trained outputs an answer according to the input of the query. Information related to the substrate processing apparatus is estimated in response to an input of the apparatus data and the image related to the substrate processing apparatus and the query requesting estimation of the information related to the substrate processing apparatus into the base model 1. For example, performance of the processed substrate may be estimated.

The base model 1 is adapted to various types of substrate processing apparatuses by training using a large number of data sets related to the various types of substrate processing apparatuses. By performing training using a large number of data sets related to individual types of substrate processing apparatuses, the base model 1 can perform an appropriate output according to various inputs related to each substrate processing apparatus. Therefore, the base model 1 has high versatility capable of performing an appropriate output in response to various inputs related to various types of substrate processing apparatuses. By using this base model 1, it is possible to estimate various types of information related to various substrate processing apparatuses. Since the base model 1 has high versatility, it is not necessary to develop a base model for each substrate processing apparatus or to tune the base model for each substrate processing apparatus. The number of man-hours required for the development or operation of the base model is reduced, and the base model 1 for estimating information related to the substrate processing apparatus 21 can be easily implemented. The answer output from the base model 1 is applied to the substrate processing apparatus 21 or to the control device that controls the substrate processing apparatus 21. For example, as illustrated in FIG. 11, when the recipe data is output from the base model 1 as the answer in response to a query requesting a proposal of recipe data, the recipe data is input into the substrate processing apparatus 21 or the control device that controls the substrate processing apparatus 21, and the substrate processing apparatus 21 performs substrate processing according to the recipe data. As illustrated in FIG. 12, when a result obtained by estimating the maintenance timing of the substrate processing apparatus 21 is output from the base model 1 as the answer, the estimated maintenance timing is applied to schedule maintenance of the substrate processing apparatus 21. As illustrated in FIG. 13, when an effective setting for improving the operating rate of the substrate processing apparatus 21 is output from the base model 1 as the answer, the setting is applied to the substrate processing apparatus 21 so that the substrate processing apparatus 21 is configured to operate at the improved operating rate. As illustrated in FIG. 10, when performance data indicating performance of the substrate processing is output from the base model 1 as the answer, the performance data, which indicates physical characteristics of the processed substrate such as defect amount, surface roughness, thickness, or critical dimension of a groove formed in the substrate, is used to evaluate a result of the substrate processing performed by the substrate processing apparatus 21. Furthermore, the answer output from the base model 1 may include diagnostic outputs that support detection of abnormal apparatus states and their diagnosis, and predictive outputs that support prediction of future apparatus performance or failure. For example, the base model 1 may output results of root-cause analysis, candidate fault hypotheses with corresponding confidence scores, estimated remaining useful life or time-to-failure, and recommended corrective or preventive actions based on the diagnosis or prediction. Such diagnostic and predictive outputs can be used to trigger automated interventions, operator alerts, or maintenance planning. In this manner, the answer output from the base model 1 may provide information and data that support or enable to control, configure, diagnose, predict, or evaluate the substrate processing performed by the substrate processing apparatus 21. For example, such information and data may include control commands or setpoints, proposed operational settings or process recipes, results of root-cause analysis, candidate fault hypotheses with associated confidence scores, estimated remaining useful life or time-to-failure, recommended corrective or preventive maintenance actions, quantitative evaluation metrics of processing results, annotated images highlighting detected defects or regions of interest, and indications of additional measurements or data to be obtained.

In the present embodiment, an example is shown in which the first model is the apparatus data encoder 11, the second model is the natural language encoder 12, the third model is the image encoder 13, and the integrated model is the integrated decoder 14. The first model, the second model, the third model, and the integrated model may be implemented by a combination of training models other than a combination in which the first model, the second model, and the third model are encoders and the integrated model is a decoder.

The invention is not limited to contents of the above-described embodiment, and various modifications may be made within the scope described in the following claims. In other words, embodiments obtained by combining technical means appropriately changed within the scope indicated in the claims are also included in the technical scope of the invention.

The features described in each embodiment can be combined with each other. In addition, the independent and dependent claims set forth in the claims can be combined with each other in any and all combinations, regardless of the reciting format. Further, the claims use a format of describing claims that recite two or more other claims (multi-claim format). However, the disclosure is not limited thereto. The claims may also be described using a format of multi-claims reciting at least one multi-claim format or multi-claim (multi-multi claims).

1. An information processing method, comprising:
inputting data related to a substrate processing apparatus into a first model, and acquiring a first feature value output by the first model,
inputting a query related to the substrate processing apparatus into a second model, and acquiring a second feature value output by the second model,
inputting the first feature value and the second feature value into an integrated model, and acquiring an answer to the query output by the integrated model, and
outputting the acquired answer,
wherein the outputted answer comprises information and data monitoring, operation, diagnosis, maintenance or prediction of the state or performance of the substrate processing apparatus.

2. The information processing method according to claim 1, further comprising:
inputting an image related to substrate processing into a third model, and acquiring a third feature value output by the third model, and
inputting the first feature value, the second feature value, and the third feature value into the integrated model, and acquiring the answer output by the integrated model.

3. The information processing method according to claim 2, wherein:
the first model, the second model, and the third model are encoders, and
the integrated model is a decoder.

4. The information processing method according to claim 1, further comprising:
inputting, as the query, performance of substrate processing into the second model,
inputting sensor data obtained from a sensor provided in the substrate processing apparatus or log data indicating a history of a state of the substrate processing apparatus into the first model as data related to the substrate processing apparatus, and
acquiring performance data indicating the performance of the substrate processing output by the integrated model as an answer to the query.

5. The information processing method according to claim 2, further comprising:
inputting, as the query, performance of substrate processing into the second model,
inputting sensor data obtained from a sensor provided in the substrate processing apparatus or log data indicating a history of a state of the substrate processing apparatus into the first model as data related to the substrate processing apparatus,
inputting an image representing a substrate before or after processing into the third model as an image related to substrate processing, and
acquiring performance data indicating the performance of substrate processing output by the integrated model as an answer to the query.

6. The information processing method according to claim 1, further comprising:
inputting into the second model, as the query, a request of a proposal of recipe data, a request of a prediction of a maintenance timing of the substrate processing apparatus, a method for increasing an operating rate of the substrate processing apparatus, or a method of dealing with an alarm of the substrate processing apparatus.

7. The information processing method according to claim 1, wherein the outputted answer comprises at least one of: recipe data for controlling the substrate processing apparatus, performance data indicating performance of substrate processing performed by the substrate processing apparatus, diagnostic outputs that support detection and diagnosis of abnormal states of the substrate processing apparatus, and predictive outputs that support prediction of future performance or failure of the substrate processing apparatus, a predicted maintenance timing of the substrate processing apparatus, or an effective setting for improving an operating rate of the substrate processing apparatus.

8. The information processing method according to claim 1, further comprising:
acquiring training data including data related to the substrate processing apparatus, a query related to the substrate processing apparatus, and an answer to the query,
collectively training the first model and the integrated model using the training data, while fixing parameters of the second model, and
next, training the integrated model using the training data.

9. An information processing apparatus, comprising:
circuitry, wherein:
the circuitry
inputs data related to a substrate processing apparatus into a first model, and acquires a first feature value output by the first model,
inputs a query related to the substrate processing apparatus into a second model, and acquires a second feature value output by the second model,
inputs the first feature value and the second feature value into an integrated model, and acquires an answer to the query output by the integrated model, and
outputs the acquired answer, and
the outputted answer comprises information and data monitoring, operation, diagnosis, maintenance or prediction of the state or performance of the substrate processing apparatus.

10. The information processing apparatus according to claim 9, wherein the circuitry further:
inputs an image related to substrate processing into a third model, and acquires a third feature value output by the third model, and
inputs the first feature value, the second feature value, and the third feature value into the integrated model, and acquires the answer output by the integrated model.

11. The information processing apparatus according to claim 10, wherein:
the first model, the second model, and the third model are encoders, and the integrated model is a decoder.

12. The information processing apparatus according to claim 11, wherein the circuitry:
inputs the query about performance of substrate processing into the second model,
inputs sensor data obtained from a sensor provided in the substrate processing apparatus or log data indicating a history of a state of the substrate processing apparatus into the first model as data related to the substrate processing apparatus,
inputs an image representing a substrate before or after processing into the third model as an image related to substrate processing, and
acquires performance data indicating the performance of substrate processing output by the integrated model as an answer to the query.

13. The information processing apparatus according to claim 9, wherein the circuitry:
inputs, as the query, a query inquiring about performance of substrate processing into the second model,
inputs sensor data obtained from a sensor provided in the substrate processing apparatus or log data indicating a history of a state of the substrate processing apparatus into the first model as data related to the substrate processing apparatus, and
acquires performance data indicating the performance of substrate processing output by the integrated model as an answer to the query.

14. The information processing apparatus according to claim 9, wherein the circuitry further:
inputs into the second model, as the query, a query requesting a proposal of recipe data, a query requesting prediction of a maintenance timing of the substrate processing apparatus, a query inquiring about a method for increasing an operating rate of the substrate processing apparatus, or a query inquiring about a method of dealing with an alarm of the substrate processing apparatus.

15. The information processing apparatus according to claim 9, wherein the outputted answer comprises at least one of: recipe data for controlling the substrate processing apparatus, performance data indicating performance of substrate processing performed by the substrate processing apparatus, diagnostic outputs that support detection and diagnosis of abnormal states of the substrate processing apparatus, and predictive outputs that support prediction of future performance or failure of the substrate processing apparatus, a predicted maintenance timing of the substrate processing apparatus, or an effective setting for improving an operating rate of the substrate processing apparatus.

16. The information processing apparatus according to claim 9, wherein the circuitry further:
acquires training data including data related to the substrate processing apparatus, a query related to the substrate processing apparatus, and an answer to the query,
collectively trains the first model and the integrated model using the training data, while fixing parameters of the second model, and
next, trains the integrated model using the training data.

17. A non-transitory computer-readable storage medium having computer-executable instructions stored thereon, which when executed by a processor, cause the processor to perform a method comprising:
inputting data related to a substrate processing apparatus into a first model, and acquiring a first feature value output by the first model,
inputting a query related to the substrate processing apparatus into a second model, and acquiring a second feature value output by the second model,
inputting the first feature value and the second feature value into an integrated model, and acquiring an answer to the query output by the integrated model, and
outputting the acquired answer,
wherein the outputted answer comprises information and data monitoring, operation, diagnosis, maintenance or prediction of the state or performance of the substrate processing apparatus.

18. The non-transitory computer-readable storage medium according to claim 17, wherein the method further comprises:
inputting an image related to substrate processing into a third model, and acquiring a third feature value output by the third model, and
inputting the first feature value, the second feature value, and the third feature value into the integrated model, and acquiring the answer output by the integrated model.

19. The non-transitory computer-readable storage medium according to claim 17, wherein the outputted answer comprises at least one of: recipe data for controlling the substrate processing apparatus, performance data indicating performance of substrate processing performed by the substrate processing apparatus, diagnostic outputs that support detection and diagnosis of abnormal states of the substrate processing apparatus, and predictive outputs that support prediction of future performance or failure of the substrate processing apparatus, a predicted maintenance timing of the substrate processing apparatus, or an effective setting for improving an operating rate of the substrate processing apparatus.

20. The non-transitory computer-readable storage medium according to claim 17, further causing the computer to execute processing of:
acquiring training data including data related to the substrate processing apparatus, a query related to the substrate processing apparatus, and an answer to the query,
collectively training the first model and the integrated model using the training data, while fixing parameters of the second model, and
next, training the integrated model using the training data.
